(19) United States
(12) Patent Application Publication
(10) Pub. No.: US 2012/0014047 A1
(43) Pub. Date: Jan. 19, 2012

(54) ELECTRONIC DEVICE

(75) Inventors: Seiya Shibata, Osaka (JP); Takashi Asano, Osaka (JP); Yukiya Maeda, Osaka (JP)

(73) Assignee: SANYO ELECTRIC CO., LTD., Osaka (JP)

(21) Appl. No.: 13/181,927

(22) Filed: Jul. 13, 2011

(30) Foreign Application Priority Data
Jul. 14, 2010 (JP) 2010-159492

(51) Int. Cl. H05K 5/02

(52) U.S. Cl. 361/679.01

(57) ABSTRACT

In an electronic device in which a sliding member and a guide trench that regulates a moving path of the sliding member are formed in the device body, a trench or a hole is formed in the first side surface of the guide trench, a movable body that can move through the trench or the hole and a biasing member that biases the movable body from the first side surface to the second side surface are arranged in the device body, the movable body can be moved between an advanced position where the movable body advances from the first side surface to the inside of the guide trench and a retracted position where the movable body is retired from the first side surface to the outside of the guide trench. A bushing member that pushes the switch in a process in which the movable body moves from the advanced position to the retracted position to change the switch over is formed on the movable body.

Japanese Patent Application No. 2010-159492 filed on Jul. 14, 2010 and serving as a base of priority claims of the present application is included in the disclosure by citation.

### TECHNICAL FIELD OF THE INVENTION

The present invention relates to an electronic device including a sliding member that slides along a surface of a device body.

### BACKGROUND ART

In an electronic device of this type, the sliding member can be moved between a closed position where a predetermined area of the surface of the device body is covered and an opened position where the predetermined area is exposed. A guide trench that regulates the moving path for the sliding member is concavely formed in the device body, and a sliding portion that is slidingly fitted in the guide trench is formed in the sliding member.

In the electronic device, in order to make the fitting between the guide trench and the sliding portion easy in the assembling step, the width of the guide trench is set to be larger than the thickness of the sliding portion. For this reason, in the assembling state of the electronic device, the sliding member is easily unstable. Therefore, in order to suppress the sliding member from being unstable, a suppressing mechanism to suppress the electronic device from being unstable may be arranged.

### SUMMARY OF THE INVENTION

An electronic device according to the present invention includes a device body, a sliding member that slides along the surface of the device body is connected to the device body, the sliding member can be moved between the closed position where the predetermined area of a surface of the device body is covered and the opened position where the predetermined area is exposed, a guide trench that regulates the moving path of the sliding member is concavely formed in the device body, and a sliding portion that is slidingly fitted in the guide trench is formed in the sliding member . In the device body, a switch that controls the operation of the device body is arranged. The switch is changed over depending on the position of the sliding member in the moving path. In this case, a trench or a hole is formed in the first side surface that is one of the two side surfaces forming the guide trench, a movable body that moves through the trench or the hole and a biasing member that biases the movable body from the first side surface to the second side surface opposing the first side surface are arranged in the device body, and the movable body can be moved between an advanced position where the movable body advances from the first side surface into the guide trench and a retracted position where the movable body is retired from the first side surface to the outside of the guide trench. On the movable body, a pressure that pushes the switch in a process in which the movable body moves from the advanced position to the retracted position to change over the switch is formed.

### BRIEF DESCRIPTION OF THE DRAWINGS

FIG. 1 is a perspective view showing a digital camera according to an embodiment of the present invention when viewed from the front surface side.

FIG. 2 is a perspective view showing the digital camera when viewed from the rear surface side.

FIG. 3 is a perspective view used in an explanation of the closed position of the sliding member included in the digital camera.

FIG. 4 is a perspective view showing a first guide trench concavely formed in the device body of the digital camera.

FIG. 5 is a sectional view along an A-A line shown in FIG. 1.

FIG. 6 is an enlarged view of a B area shown in FIG. 5.

FIG. 7 is an enlarged view of a C area shown in FIG. 5.

FIG. 8 is a perspective view of the sliding member when viewed from the rear surface side.

FIG. 9 is an enlarged view of a D area shown in FIG. 8.

FIG. 10 is a perspective view of the sliding member when viewed from the rear surface side at an angle different from that in FIG. 8.

FIG. 11 is an enlarged view of an E area shown in FIG. 10.

FIG. 12 is a perspective view of the device body of the digital camera from which a rear-surface-side half case is removed when viewed from the rear side surface.

FIG. 13 is a perspective view showing a board arranged in the device body and a switch mounted on the board.

FIG. 14 is a plan view showing the device body from which the front-surface-side half case and the sliding member are removed when viewed from the left-side surface.

FIG. 15 is a plan view used in an explanation of the first state of the movable body change depending on the position of the sliding member on the moving path.

FIG. 16 is a plan view used in an explanation of the second state of the movable body change depending on the position of the sliding member on the moving path.

FIG. 17 is a plan view used in an explanation of the third state of the movable body change depending on the position of the sliding member on the moving path.

FIG. 18 is a plan view used in an explanation of the fourth state of the movable body change depending on the position of the sliding member on the moving path.

FIG. 19 is a sectional view along an F-F line shown in FIG. 14.

FIG. 20 is a sectional view showing a state in which a lever of the switch is pushed by pressure.

FIG. 21 is a diagram showing the main part of a modification of the digital camera.

### DETAILED DESCRIPTION OF PREFERRED EMBODIMENTS

A form in which the present invention is applied to a digital camera will be described below in detail with reference to the accompanying drawings.

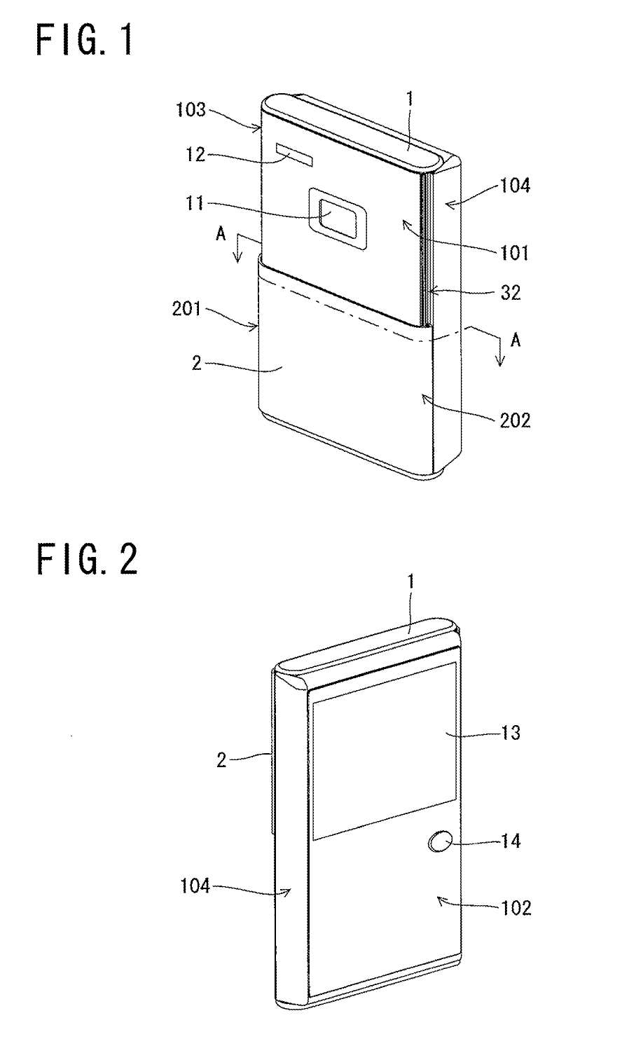

FIG. 1 is a perspective view showing a digital camera according to an embodiment of the present invention when viewed from the front surface side, and FIG. 2 is a perspective view showing the digital camera when viewed from the rear surface side. As shown in FIG. 1, the digital camera according to the embodiment includes a device body 1 extending lengthways in a vertical direction, and an optical lens 11 and a flash lamp 12 are arranged in the upper area of the front surface 101 of the device body 1. As shown in FIG. 2, on the rear surface 102 of the device body 1, a liquid crystal display panel 13 is arranged in the upper area. On the other hand, an operation button 14 is arranged in the lower area of the rear surface 102.

As shown in FIG. 1, a sliding member 2 that vertically slides along the front surface 101 is connected to the device body 1. In this case, the sliding member 2 is configured by a metal plate having a small thickness and shape along the front surface 101 of the device body 1. The sliding member 2 has both left and right end portions 201 and 202 which go around on the left side surface 103 and the right side surface 104 of the device body 1, respectively.

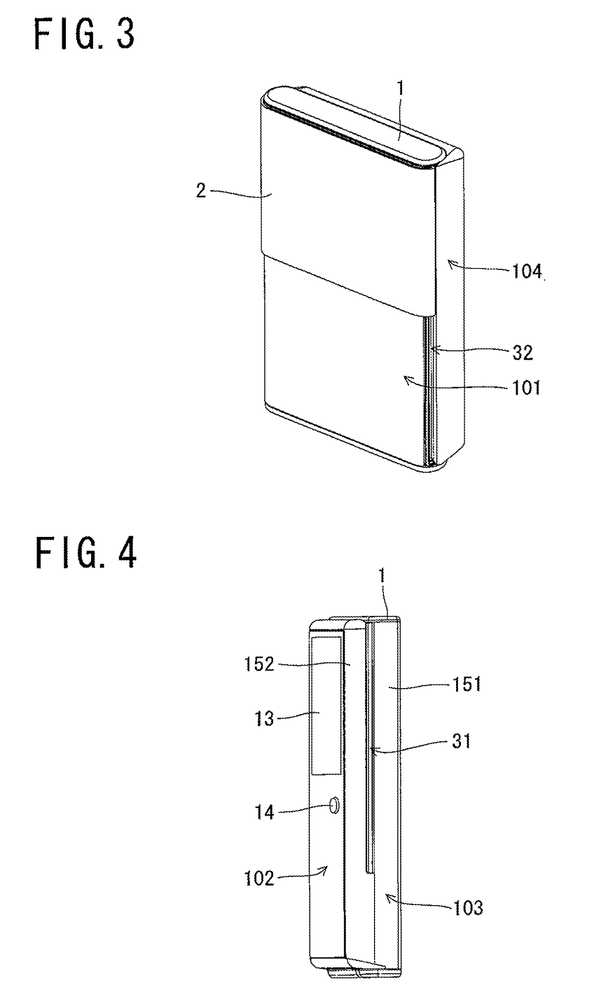

The sliding member 2 can be moved between a closed position where, as shown in FIG. 3, the upper area of the front surface 101 of the device body 1 is covered and an opened position where, as shown in FIG. 1, the upper area is exposed. When the sliding member 2 is set to the closed position, as shown in FIG. 3, the optical lens 11 is hidden on the rear surface side of the sliding member 2. On the other hand, when the sliding member 2 is set to the opened position, as shown in FIG. 1, the optical lens 11 appears on the front surface 101 of the device body 1.

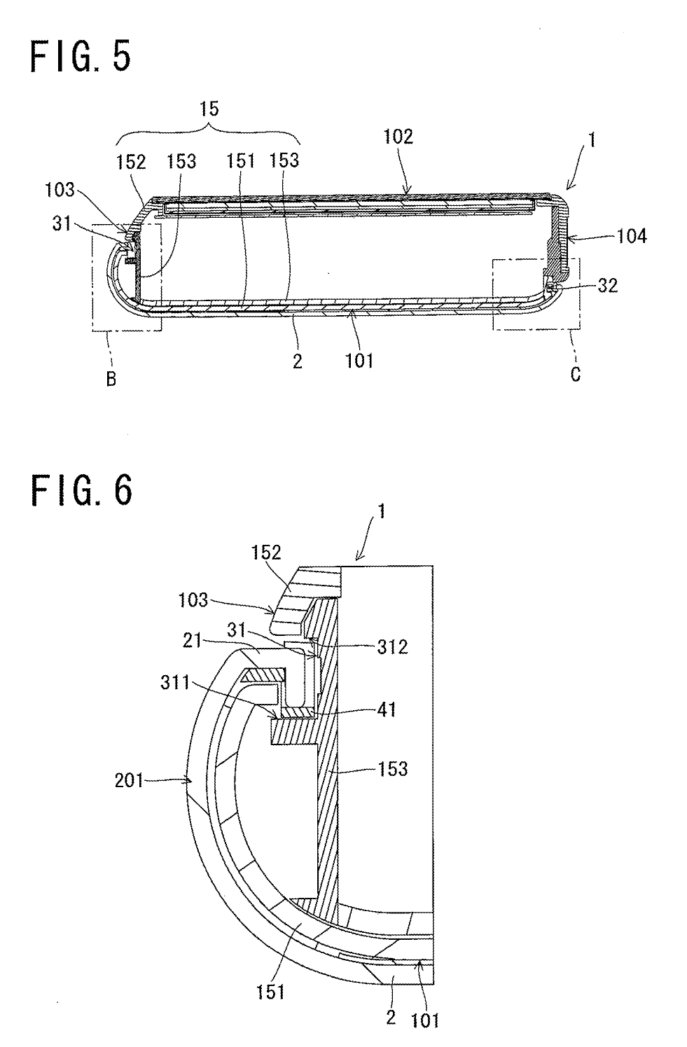

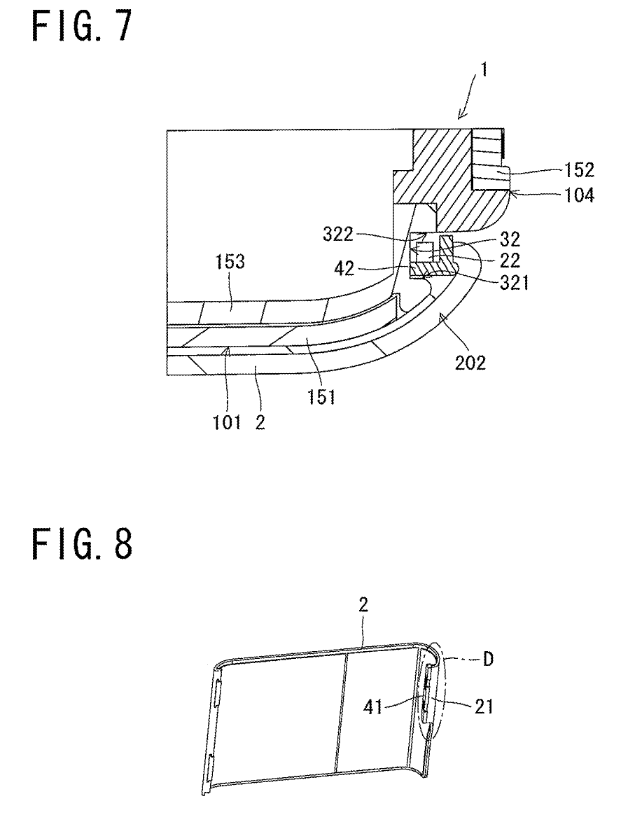

FIG. 5 is a sectional view along an A-A line shown in FIG. 1. FIGS. 6 and 7 are enlarged views of a B area and a C area shown in FIG. 5. As shown in FIGS. 5 to 7, in the device body 1, on the left side surface 103 and the right side surface 104, the first guide trench 31 and the second guide trench 32 that regulate the moving paths of the sliding member 2 are concavely formed. More specifically, the first guide trench 31, as shown in FIG. 4, vertically extends in the left side surface 103 of the device body 1. On the other hand, the second guide trench 32, as shown in FIGS. 1 and 3, vertically extends in the right side surface 104 of the device body 1.

As shown in FIG. 5, a case 15 that forms an outer peripheral surface of the device body 1 is configured such that a metal front-surface-side half case 151 and a resin rear-surface-side half case 152 are attached to a resin underbody 153. As shown in FIGS. 6 and 7, the resin underbody 153 is partially exposed on the left side surface 103 and the right side surface 104 of the device body 1, and the first guide trench 31 and the second guide trench 32 are formed in the exposed portions of the underbody 153, respectively.

On the other hand, on the sliding member 2, a first sliding portion 21 is slidingly fitted into the first guide trench 31 by a bending deformation of the left end portion 201. Furthermore, on the sliding member 2, a second sliding portion 22 that is slidingly fitted into the second guide trench 32 by a bending deformation of the right end portion 202 of the sliding member 2.

As shown in FIG. 6, of the front and rear side surfaces 311 and 312 that form the first guide trench 31, between the front side surface 311 and the first sliding portion 21, a first resin member 41 is interposed. An engagement mechanism that engages the first sliding portion 21 and the first resin member 41 with each other is arranged between the first sliding portion 21 and the first resin member 41. As shown in FIG. 7, of the front and rear side surfaces 321 and 322 that form the second guide trench 32, between the front side surface 321 and the second sliding portion 22, a second resin member 42 is interposed. An engagement mechanism that engages the second sliding portion 22 and the second resin member 42 with each other is arranged between the second sliding portion 22 and the second resin member 42.

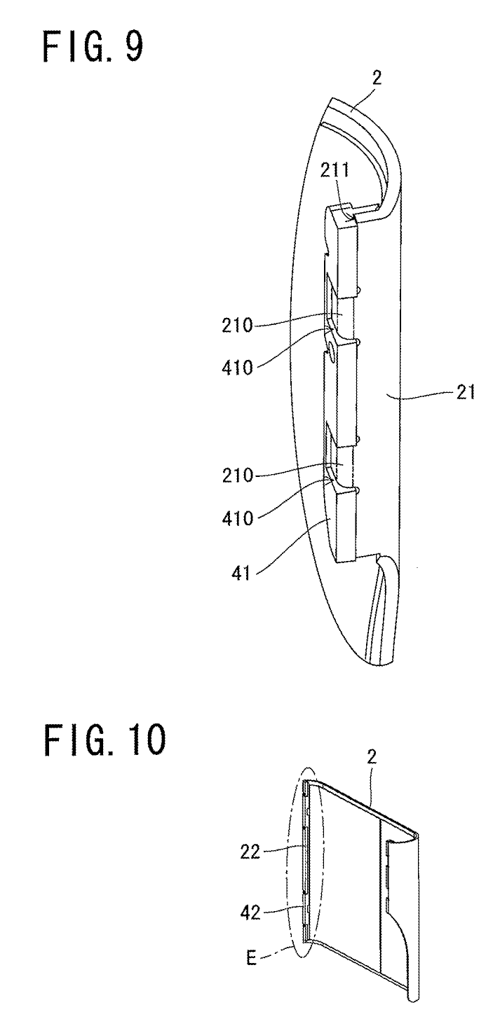

FIG. 8 is a perspective view showing the sliding member 2 when viewed from the rear surface side, and FIG. 9 is an enlarged view of a D area shown in FIG. 8. As shown in FIG. 9, a pair of the engagement portions 210 is projected from the first sliding portion 21. On the other hand, an engaged portion 410 with which each of the engagement portions 210 of the first sliding portion 21 are engaged, is concavely formed in the first resin member 41. Therefore, each of the engagement portions 210 of the first sliding portion 21 are engaged with the engagement portion 410 of the corresponding first resin member 41 to prevent the first resin member 41 from shifting from a predetermined position on the first sliding portion 21 in a direction along the first guide trench 31. Each of the engagement portions 210 of the first sliding portion 21 is formed by a bending deformation of the tongue part formed at a distal end 211 of the first sliding portion 21 in an L shape.

In this manner, each of the engagement portions 210 of the first sliding portion 21 and the engagement portion 410 of the first resin member 41 are engaged with the engagement portions 210 and the engagement mechanism that engages the first sliding portion 21 and the first resin member 41 with each other is configured.

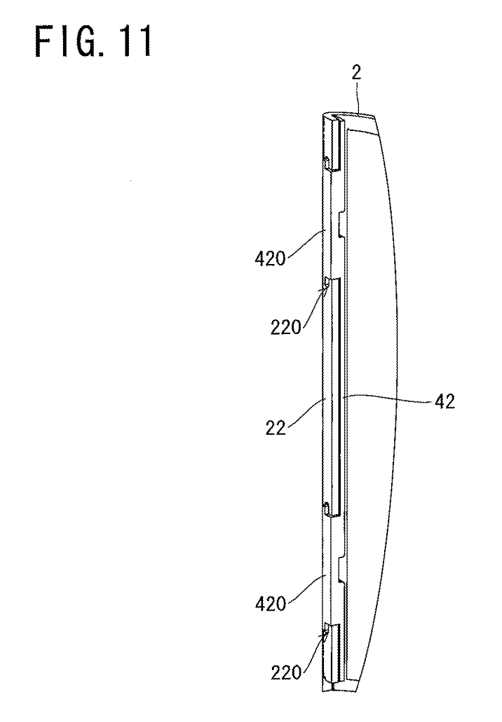

FIG. 10 is a perspective view showing the sliding member 2 when viewed from the rear surface side at an angle different from that in FIGS. 8, and 11 is an enlarged view of an E area shown in FIG. 10. As shown in FIG. 11, a pair of engagement portions 420 is projected from the second resin member 42. On the other hand, in the second sliding portion 22, an engagement portion 220 with which each of the engagement portions 420 of the second resin member 42 is engaged is concavely formed. Therefore, each of the engagement portions 420 of the second resin member 42 is engaged with the engaged portion 220 of the corresponding second sliding portion 22 to prevent the second resin member 42 from shifting from a predetermined position on the second sliding portion 22 in a direction along the second guide trench 32.

In this manner, each of the engagement portions 420 of the second sliding portion 42 and the engaged portion 220 of the second sliding portion 22 are engaged with the engagement portions 420 and the engagement mechanism that engages the second sliding portion 22 and the second resin member 42 with each other is configured.

In the digital camera, the first resin member 41 prevents the first sliding portion 21 from being in contact with the front side surface 311 of the first guide trench 31. The first resin member 41 is brought into contact with the front side surface 311 of the first guide trench 31. Therefore, the side surface 311 of the first guide trench 31 is difficult to be worn out in comparison with a case in which the metal first sliding portion 21 is in contact with the side surface 311. According to the digital camera, wearing of the front side surface 311 of the first guide trench 31 is reduced by the first resin member 41.

For the same reason as described above, wearing of the front side surface 321 of the second guide trench 32 is reduced by the second resin member 42.

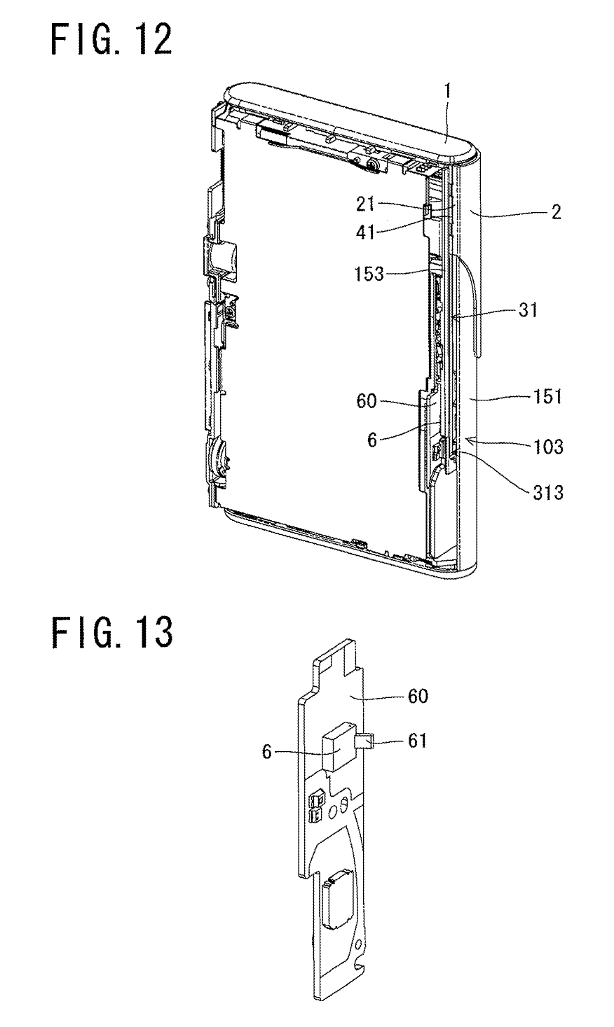

FIG. 12 is a perspective view of the device body 1 of the digital camera from which the rear-surface-side half case 152 is removed when viewed from the rear surface side. As shown in FIG. 12, in the device body 1, at a position near the lower end 313 of the first guide trench 31, a board 60 is arranged along the rear surface of the underbody 153 in which the first guide trench 31 is formed. On the board 60, a switch 6 to ON/OFF-control the power supply of the device body 1 is mounted. In this case, as shown in FIG. 13, a lever 61 for the charging-over operation of the switch 6 is arranged on the switch 6.

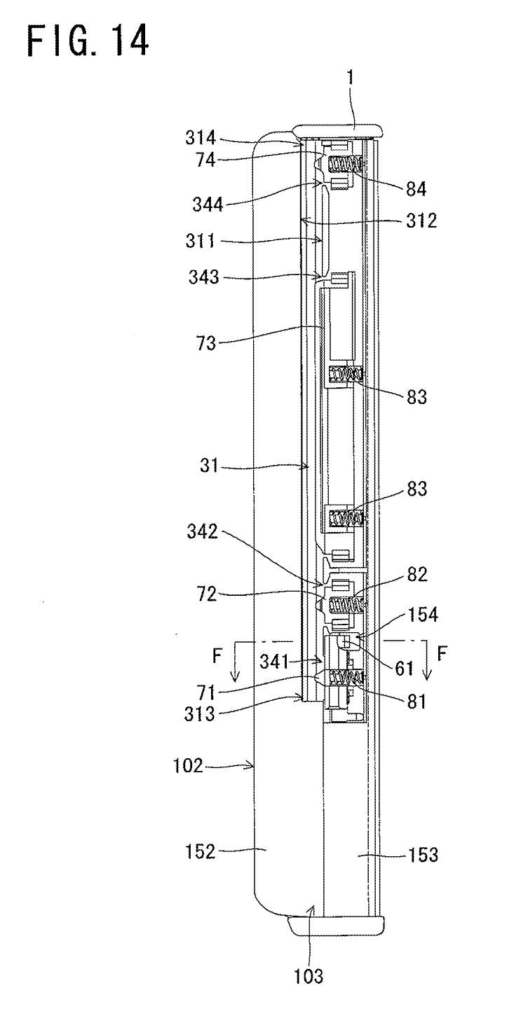

FIG. 14 is a plan view showing the device body 1 from which the front-surface-side half case 151 and the sliding member 2 are removed when viewed from the left-side surface 103. As shown in FIG. 14, on the underbody 153 in which the first guide trench 31 is formed, an area opposing the lever 61 of the switch 6, an opening 154 that penetrates the underbody 153 from the upper surface thereof to the rear surface is formed.

On the side surface 311 of the pair of front and rear side surfaces 311 and 312 that form the first. guide trench 31, four transverse trenches 341 to 344 are formed. More specifically, on the front side surface 311, the first transverse trench 341 is formed in an area near the lower end 313 of the first guide trench 31, the second transverse trench 342 is formed in an area immediately above the formed area of the first transverse trench 341, the third transverse trench 343 vertically extending lengthways in the central area, and the fourth transverse trench 344 is formed in an area near the upper end 314 of the first guide trench 31.

In the device body 1, the four movable bodies 71 to 74 that can move through the transverse trenches 341 to 344, respectively, and four compression coil springs 81 to 84 that bias the movable bodies 71 to 74 from the front side surface 311 of the first guide trench 31 to the rear side surface 312 are arranged. The four movable bodies 71 to 74 can be moved between an advanced position where the movable bodies 71 to 74 advance from the front side surface 311 of the first guide trench 31 to the inside of the first guide trench 31 and a retracted position where the movable bodies 71 to 74 are retired from the side surface 311 to the outside of the first guide trench 31. The four compression coil springs 81 to 84 have one end connected to the movable bodies 71 to 74, and have other ends connected to the underbody 153 in which the first guide trench 31 is formed.

In this case, of the four movable bodies 71 to 74, the first movable body 71, the second movable body 72, and the fourth movable body 74 that move through the first transverse trench 341, the second transverse trench 342, and the fourth transverse trench 344 are tapered toward the inside of the first guide trench 31. The third movable body 73 that moves through the third transverse trench 343 has a shape with a flat distal end face.

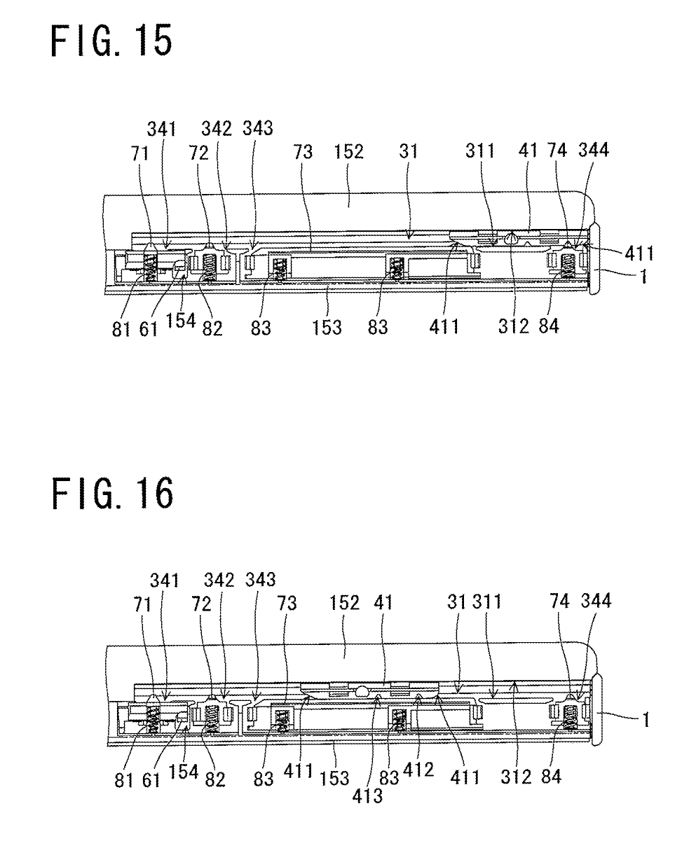

FIGS. 15 to 18 are plan views used in explanations of first to fourth states of the four movable bodies 71 to 74 changing depending on the positions of the sliding member 2 on the moving path, respectively. As shown in FIGS. 15 to 18, in the first resin member 41 that slides in the first guide trench 31 there along, on both end faces in the direction along the first guide trench 31, cam surfaces 411 are formed.

When the sliding member 2 is set to a position between the closed position and the opened position to cause the first resin member 41 to face the third transverse trench 343 as shown in FIG. 16, the third movable body 73 is pushed with the resin member 41 and moves from the advanced position to the retracted position against a biasing force of a compression coil spring 83. In this manner, the compression coil spring 83 is compressed to set the third movable body 73 to the retired position. On the other hand, in the state (second state) shown in FIG. 16, the first resin member 41 receives a flexible repulsive force from the compression coil spring 83 through the third movable body 73. Therefore, the first resin member 41 is pushed against the rear side surface 312 of the first guide trench 31. As a result, the sliding member 2 is suppressed from being unstable.

When the sliding member 2 slides from the position shown in FIG. 16 to the closed position (see FIG. 15), in this process, a tapered end portion of the fourth movable body 74 is brought into contact with the cam surface 411 of the resin member 41. With a cam action between the cam surface 411 and the tapered end portion, the fourth movable body 74 moves from the advanced position to the retracted position against the biasing force of the compression coil spring 84. In this manner, the compression coil spring 84 is compressed to set the fourth movable body 74 to the retracted position. Thereafter, when the sliding member 2 is set to the closed position, as shown in FIG. 15, the first resin member 41 faces the fourth transverse trench 344.

At this time, the first resin member 41 still faces part of the third transverse trench 343. Therefore, the third movable body 73 is still set to the retracted position. Therefore, not only in the second state but also in the state (first state) shown in FIG. 15, the first resin member 41 receives a flexible repulsive force from the compression coil spring 83 through the third movable body 73. Therefore, the first resin member 41 is pushed against the rear side surface 312 of the first guide trench 31. As a result, the sliding member 2 is suppressed from being unstable.

On the first resin member 41, the first recessed portion 412 (see FIG. 16) in which the tapered end portion of the fourth movable body 74 is fitted in the first state is formed. Therefore, when the sliding member 2 slides to be set to the closed position, the tapered end portion of the fourth movable body 74 is fitted in the first recessed portion 412 with the biasing force of the compression coil spring 84. For this reason, a click feeling can be generated.

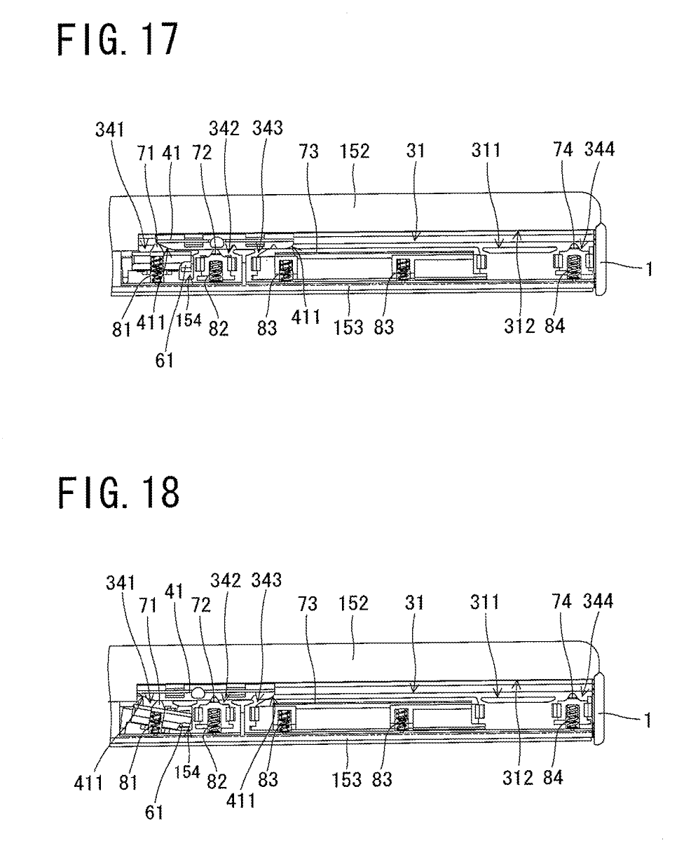

On the other hand, when the sliding member 2 slides from the position shown in FIG. 16 to the opened position (see FIG. 17), in this process, the tapered end portion of the second movable body 72 is brought into contact with the cam surface 411 of the resin member 41. With the cam action between the cam surface 411 and the tapered end portion, the second movable body 72 moves from the advanced position to the retracted position against the compression coil spring 82. For this reason, the compression coil spring 82 is compressed to set the second movable body 72 to the retracted position. Thereafter, when the sliding member 2 further slides, as shown in FIG. 17, the first resin member 41 faces the second transverse trench 342.

At this time, the first resin member 41 still faces part of the third transverse trench 343. Therefore, the third movable body 73 is still set to the retracted position. Therefore, not only in the second state but also in the state (third state) shown in FIG. 17, the first resin member 41 receives an elastic repulsive force from the compression coil spring 83 through the third movable body 73. Therefore, the first resin member 41 is pushed against the rear side surface 312 of the first guide trench 31. As a result, the sliding member 2 is suppressed from being unstable.

Furthermore, when the sliding member 2 slides from the position shown in FIG. 17 to the opened position (see FIG. 18), in this process, the tapered end portion of the first movable body 71 is brought into contact with the cam surface 411 of the resin member 41. With the cam action between the cam surface 411 and the tapered end portion, the first movable body 71 moves from the advanced position to the retracted position against the compression coil spring 31. In this manner, the compression coil spring 81 is compressed, and the first movable body 71 is set to the retracted position. Thereafter, when the sliding member 2 is set at to the opened position, as shown in FIG. 18, the first resin member 41 faces the first transverse trench 341.

On the other hand, in the state (fourth state) shown in FIG. 18, the first resin member 41 receives a flexible repulsive force from the compression coil spring 81 through the first movable body 71 . Also in the fourth state, the first resin member 41 still faces a part of the third transverse trench 343. Therefore, the third movable body 73 is still set to the retracted position. Therefore, the first resin member 41 also receives a flexible repulsive force from the compression coil spring 83 through the third movable body 73. Therefore, the first resin member 41 is pushed against the rear side surface 312 of the first guide trench 31. As a result, the sliding member 2 is suppressed from being unstable.

On the first resin member 41, the second recessed portion 413 (see FIG. 16) in which the tapered end portion of the fourth movable body 72 is fitted in the fourth state is formed. Therefore, when the sliding member 2 slides to be set to the opened position, the tapered end portion of the second movable body 72 is fitted in the second recessed portion 413 with the biasing force of the compression coil spring 82. For this reason, a click feeling can be generated.

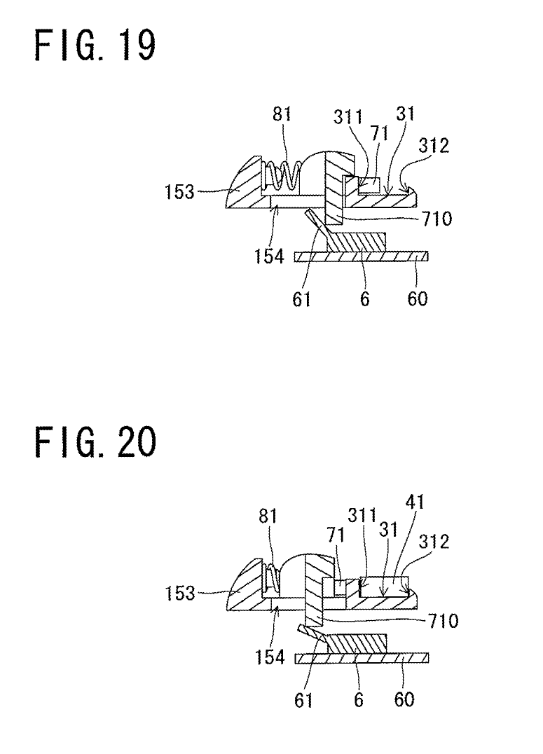

FIG. 19 is a sectional view along an F-F line shown in FIG. 14. As shown in FIG. 19, of the four movable bodies 71 to 74, on the first movable body 71 that moves through the first transverse trench 341, a pushing member 710 that penetrates the opening 154 to be brought into contact with the lever 61 of the switch 6 is formed integrally with the first movable body 71. In this case, as shown in FIG. 20, in the process in which the first movable body 71 moves from the advanced position to the retracted position, the pushing member 710 pushes the lever 61 of the switch 6 to push the lever 61 down so as to change the switch 6 over.

Therefore, in the digital camera, the first movable body 71 moves between the advanced position and the retracted position depending on the opening/closing operation of the sliding member 2 as shown in FIGS. 15 to 18. Accordingly, the switch 6 is changed over.

More specifically, when the sliding member 2 is set to the opened position, as shown in FIG. 18, the first movable body 71 is moved from the advanced position to the retracted position. In this manner, as shown in FIG. 20, the pushing member 710 pushes the lever 61 of the switch 6. As a result, the switch 6 is changed over to turn on the power supply of the device body 1. On the other hand, when the sliding member 2 slides from the opened position to the closed position, as shown in FIG. 17, the first movable body 71 moves from the retracted position to the advanced position by the biasing force of the compression coil spring 81. In this manner, as shown in FIG. 19, the lever 61 is released from being pushed by the pushing member 710. As a result, the switch 6 returns to the original state to turn the power supply of the device body 1 off.

Therefore, in the digital camera, the changing-over operation of the switch 6 depending on the opening/closing state of the sliding member 2 and the suppression of the instability of the sliding member 2 are realized by one mechanism including the first movable body 71 and the compression coil spring 81 that biases the first movable body 71 with a spring force. Therefore, according to the digital camera, the changing-over operation of the switch 6 depending on the opening/closing state of the sliding member 2 and the suppression of the instability of the sliding member 2 are realized without increasing the number of parts constituting the digital camera.

In the digital camera, furthermore, a mechanism to suppress the sliding member 2 from being unstable is configured by the mechanism including the third movable body 73 and the compression coil spring 83 that biases the third movable body 73 with a spring force. Therefore, not only at the opened position but also over the entire area between the opened position and the closed position, the sliding member 2 is suppressed from being unstable. These mechanisms to suppress instability may not have only the function of suppressing instability but also the function of holding the sliding member 2 on the device body 1.

In the digital camera, the fourth movable body 74, compression coil spring 84 that biases the fourth movable body 74 with a spring force, and the first recessed portion 412 formed in the first resin member 41 constitute a mechanism that generates a click sensation when the sliding member 2 is set to the closed position. The second movable body 72, the compression coil spring 82 that biases the second movable body 72 with a spring force, and the second recessed portion 413 formed in the first resin member 41 constitute a mechanism that generates a click sensation when the sliding member 2 is set to the opened position. These mechanisms may not have only the function to generate a click sensation but also the function of suppressing the sliding member 2 from being unstable.

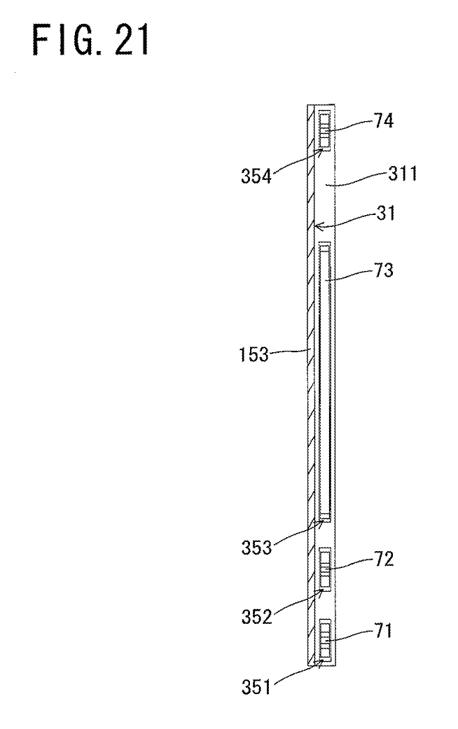

FIG. 21 is a diagram showing the main part of a modification of the digital camera. As shown in FIG. 21, in the digital camera, in the front side surface 311 of the first guide trench 31, in place of the four transverse trenches 341 to 344, four holes 351 to 354 may be formed, and the movable bodies 71 to 74 may be moved between the advanced position and the retracted position through the holes 351 to 354, respectively. As a matter of fact, in the front side surface 311 of the first guide trench 31, in place of any one of the four transverse trenches 341 to 344, a hole may be formed.

The configurations of the portions of the present invention are not limited to this embodiment, and the configurations can be variously changed without departing from the technical essence and scope of the invention. For example, in the digital camera, the switch 6 may be not only to ON/OFF-control the power supply of the device body 1 but also to control various operations of the device body 1. In the digital camera, the switch 6 may be changed over when the sliding member 2 is set to the closed position or at a position between the closed position and the opened position. When the configurations are combined to each other, the switch 6 can be changed over depending on the position of the sliding member 2 on the moving path.

By applying each of the various configurations employed in the digital camera to a digital camera that does not include the first resin member 41, the first sliding portion 21 of the sliding member 2 is pressed on to the rear side surface 312 of the first guide trench 31, and the sliding member 2 may be suppressed from being unstable.

The various configurations employed in the digital cameras can also be applied to a digital camera in which the sliding member 2 slides in a predetermined direction (for example, horizontal directions) along the front surface of the device body 1. The various configurations employed in the digital cameras can be applied to various electronic devices including sliding members that slide along the front surfaces of the device bodies.

What is claimed is:

1. An electronic device which includes a device body and in which a sliding member that slides along the surface of the device body is connected. to the device body, the sliding member can be moved between a closed position where a predetermined area of a surface of the device body is covered and an opened position where the predetermined area is exposed, a guide trench that regulates the moving path of the sliding member is concavely formed in the device body, a sliding portion that is slidingly fitted into the guide trench is formed in the sliding member, a switch that controls the operation of the device body is further arranged on the device body, and the switch is changed over depending on the position of the sliding member on the moving path, wherein a trench or a hole is formed in the first side surface that is one of two side surfaces forming the guide trench, a movable body that can move through the trench or the hole and a biasing member that biases the movable body from the first side surface to the second side surface opposing the first side surface are arranged in the device body, the movable body can be reciprocated between an advanced position where the movable body advances from the first side surface to the inside of the guide trench and a retracted position where the movable body is retired from the first side surface to the outside of the guide trench, and a pushing member that pushes the switch in a process in which the movable body moves from the advanced position to the retracted position to change the switch over, is formed on the movable body.

2. The electronic device according to claim 1, wherein a cam mechanism is formed on the sliding portion and the movable body, and, in a process in which the sliding member slides to a predetermined position where the sliding portion faces the trench or the hole, by a cam action of the cam mechanism, the movable body moves from the advanced position to the retracted position against the biasing force of the biasing member.

3. The electronic device according to claim 1, wherein a lever for a changing-over operation of the switch is arranged on the switch, and the lever is pushed with a pushing member in a process in which the movable body moves from the advanced position to the retracted position to change the switch over.
